(19) United States
(12) Patent Application Publication
(10) Pub. No.: US 2007/0200576 A1
(43) Pub. Date: Aug. 30, 2007

(54) Multi-layered probes

(76) Inventors: Edward T. Laurent, Ambler, PA (US); Edward L. Malantonio, Conshohocken, PA (US); Richard D. Sadler, Quakertown, PA (US); Bahadir Tunaboylu, Chandler, AZ (US); Brian McHugh, Phoenix, AZ (US); Dov Chartarifsky, Chandler, AZ (US)

Correspondence Address: HICKMAN PALERMO TRUONG & BECKER, LLP, 2055 GATEWAY PLACE, SUITE 550, SAN JOSE, CA, 95110, US

(21) Appl. No.: 11/703,875

(22) Filed: Feb. 7, 2007

Related U.S. Application Data
(60) Provisional application No. 60/771,339, filed on Feb. 8, 2006.

(51) Int. Cl. G01R 31/02

(52) U.S. Cl. 324/754

(57) ABSTRACT

A probe for a probe card assembly is provided. The probe has a post structure supported by a substrate, a plurality of stacked beam elements disposed on the post structure, and a tip attached to a surface of a top beam element, of the plurality of stacked beam elements, that opposes the substrate. The tip is configured to be electrically connected to a semiconductor device to be tested. The probe may be bent so that the tip is further away from the substrate than the height the post structure. The effective maximum force exerted by the tips of a multi-beamed probe against, for example, DUT pads may be increased when compared to prior probes.

### RELATED APPLICATION DATA

This application claims the benefit of, and priority to, U.S. Provisional Patent Application No. 60/771,339, entitled Multi-layered Probes, filed on Feb. 8, 2006, the contents of which are incorporated by reference for all purposes as if fully set forth herein.

### FIELD OF THE INVENTION

The present invention relates to probes for a probe card assembly.

### BACKGROUND

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Probe cards and/or probe card assemblies include an array of probes for achieving electrical contact between a testing system or the like and a device under test (DUT). The array of probes is designed to correspond to array of pads and/or testing areas to be contacted on the DUT. Increased contact force between each probe and corresponding DUT pad to be tested is generally desired.

FIG. 1 is a side view of a probe 150 that may be referred to as a cantilever probe. Cantilever probe 150 includes beam 104 which is attached to post 102 at the lower surface of one end of beam 104. Tip 106 is connected to the upper surface proximate the other end of beam 104. Post 102 is in turn connected to substrate 108. Line 110 is the interface between post 102 and substrate 108 and may represent a pad or a trace line electrically connected to a distal pad (not shown) formed on substrate 108.

U.S. Provisional Patent Application No. 60/722,351 and U.S. patent application Ser. No. 11/211,994 relate to probe elements and are each incorporated herein by reference in their entirety for all purposes.

In cantilever probe 150 shown in FIG. 1, the beams and posts may each be comprised of gold (Au) plated nickel manganese (NiMn) for example. The tips may be, for example, a single bumped tip or a stacked tip as in U.S. patent application Ser. No. 11/211,994 incorporated by reference in its entirety or other tip forms. The substrates may be, for example, multi-layered ceramic (MLC), multi-layered organic (MLO), etc. and may be space transformers.

When employed in testing a device under test (DUT), probe 150 is positioned adjacent the DUT (not shown) so that contact is made between the upper end of tip 106 and a desired pad/testing area (not shown) of the DUT. While it is desirable to increase the force exerted by tip 106 against the DUT pad that would generally involve lengthening beam 104. However, due to the pitch, or distance between tips 106 on adjacent/proximate cantilever probes 150, used to test ever smaller pitched DUT pads, there may not be sufficient room or distance to effectively do so.

### BRIEF DESCRIPTION OF THE DRAWINGS

Embodiments of the present invention are illustrated by way of example, and not by way of limitation, in the figures of the accompanying drawings and in which like reference numerals refer to similar elements and in which:

FIG. 1 is a side view of an exemplary cantilever probe;

FIG. 2 is a side view of a structure common to the first, second and fourth according to an embodiment of the invention;

FIG. 3 is a side view of a structure common to the first and second according to an embodiment of the invention;

FIG. 4 is a multi-layered probe according to an embodiment of the invention;

FIG. 5 is a multi-layered probe according to an embodiment of the invention;

FIG. 6 is a multi-layered probe according to an embodiment of the invention;

FIG. 7 is a multi-layered probe according to an embodiment of the invention;

FIG. 8 is a side view of a probe according to an embodiment of the invention; and

FIGS. 9A-9C are top views of beam panels according to an embodiment of the invention.

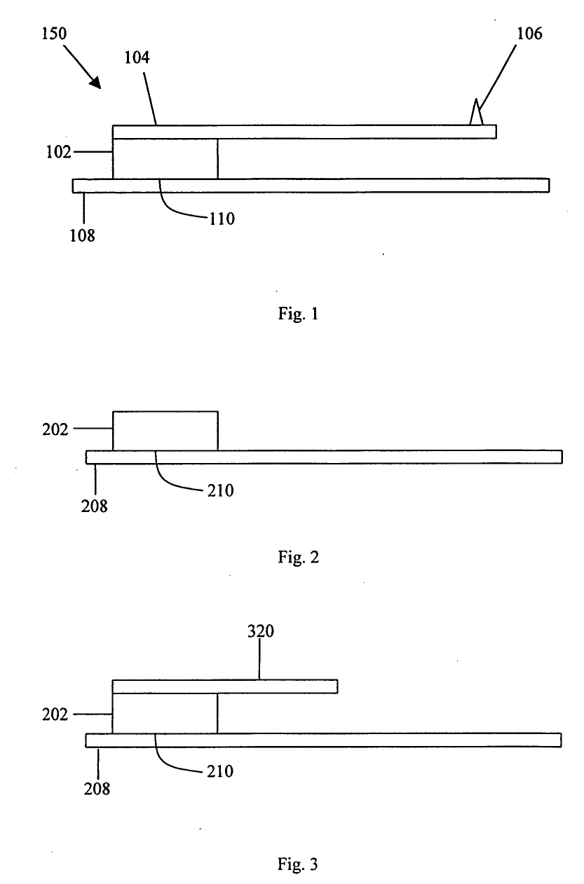

### DETAILED DESCRIPTION

In the following description, for the purposes of explanation, numerous specific details are set forth in order to provide a thorough understanding of the embodiments of the invention described herein. It will be apparent, however, that the embodiments of the invention described herein may be practiced without these specific details. In other instances, well-known structures and devices are shown in block diagram form in order to avoid unnecessarily obscuring the embodiments of the invention described herein.

The invention is best understood from the following detailed description when read in connection with the accompanying drawing. It is emphasized that, according to common practice, the various features of the drawing are not to scale. On the contrary, the dimensions of the various features are arbitrarily expanded or reduced for clarity. In the description, relative terms such as “horizontal,” “vertical,” “up,” “down,” “top,” and “bottom” as well as derivatives thereof (for example, “horizontally,” “downwardly,” “upwardly,” etc.) should be construed to refer to the orientation as then described or as shown in the drawing figure under discussion unless otherwise specifically described. These relative terms are for convenience of description and normally are not intended to require a particular orientation. Terms “inwardly,” “outwardly,” “longitudinal” versus “lateral” and the like are to be interpreted relative to one another or relative to an axis of elongation, or an axis or center of rotation, as appropriate. Terms such as “connected” and “interconnected” refer to a relationship wherein structures are secured or attached to one another either directly or indirectly through intervening structures, as well as both movable or rigid attachments or relationships, unless expressly described otherwise. The term “operatively connected” is such an attachment, coupling or connection that allows the pertinent structures to operate as intended by virtue of that relationship.

Embodiments of the invention advantageously provide for forming probes having multi-layers of beams (multi-layered probes). Using the multi-layered probes, the effective maximum force exerted by the tips of the probes against, for example, DUT pads may be increased.

In an embodiment, a probe for a probe card assembly comprises a post structure supported by a substrate, a plurality of stacked beam elements disposed on the post structure, and a tip attached to a surface of a top beam element, of the plurality of stacked beam elements, that opposes the substrate. The tip is configured to be electrically connected to a semiconductor device to be tested.

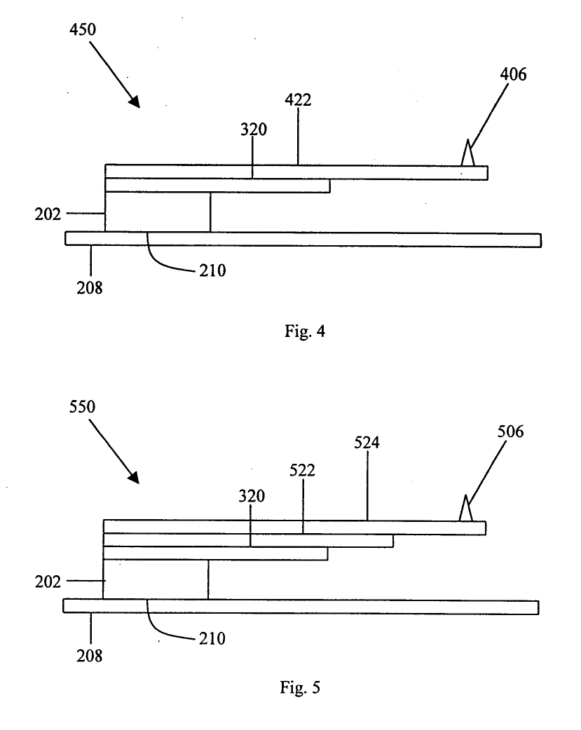

FIG. 4 is illustrates a multi-layered probe according to an embodiment of the present invention with FIGS. 2 and 3 illustrating steps in the formation of multi-layered probe 450 as described herein. As shown in FIG. 2, post 202 is connected to substrate 208 at interface 210. Post 202 may be, for example, plated-up (using processes such as, for example, lithographic processes, such as, for example, photolithographic, stereolithographic, or X-ray lithographic processes, etc.) over a trace (not shown) leading to a distal substrate pad (not shown) as represented at interface 210. Post 202 may also be, for example, formed separately and then bonded to substrate 208 at interface 201 by, for example, tab bonding. A separate sheet of an array of posts 202 (a post panel) may also be formed corresponding to the spacing and pattern of the array of trace elements/substrate pads and then aligned and bonded (e.g., tab bonded) to the corresponding trace elements/substrate pads in a group.

As shown in FIG. 4, the beams and posts of multi-layered probe 450 may each be comprised of gold (Au) plated nickel manganese (NiMn), for example. The tips may be, for example, a single bumped tip or a stacked tip as in U.S. patent application Ser. No. 11/211,994 incorporated by reference in its entirety or other tip forms. The substrates may be, for example, multi-layered ceramic (MLC), multi-layered organic (MLO), etc. and may be space transformers.

As shown in FIG. 3, the first of a series of first beams 320 having a first length is then connected at its lower surface proximate one end to the upper surface of corresponding post 202 by, for example, tab bonding. A separate sheet of an array of, for example plated-up (using processes such as, for example, lithographic processes, such as, for example, photolithographic, stereolithographic, or X-ray lithographic processes, etc.), first beams 320 (a beam panel) may also be formed corresponding to the spacing and pattern of the array of posts 202 and then aligned and tab bonded to the corresponding posts 202 en masse.

As shown in FIG. 4, the first of a series of second beams 422 (with tip 406 connected to the upper surface proximate one end of second beam 422) and having a second length greater than the first length of first beam 320 is then connected at its lower surface proximate the other end of second beam 422 to the upper surface of first beam 320 by, for example, tab bonding to form multi-layered probe 450. A separate sheet of an array of, for example plated-up (using processes such as, for example, lithographic processes, such as, for example, photolithographic or X-ray lithographic processes, etc.), second beams 422 with connected tips 406 (a beam panel) may also be formed corresponding to the spacing and pattern of the array of first beams 320 and then aligned and tab bonded to the corresponding first beams 320 en masse.

FIG. 5 is a multi-layered probe embodiment of the invention with FIGS. 2 and 3 illustrating exemplary steps in the formation of multi-layered probe 550 (the description of which will not be repeated here). As shown in FIG. 5, the first of a series of second beams 522 and having a second length greater than the first length of first beam 320 (also see FIG. 3) is then connected at its lower surface proximate one end of second beam 522 to the upper surface of first beam 320 by, for example, tab bonding. A separate sheet of an array of, for example plated-up (using processes such as, for example, lithographic processes, such as, for example, photolithographic, stereolithographic, or X-ray lithographic processes, etc.), second beams 522 may also be formed corresponding to the spacing and pattern of the array of first beams 320 and then aligned and tab bonded to the corresponding first beams 320 en masse.

The first of a series of third beams 524 (with tip 506 connected on the upper surface proximate one end of third beam 524) and having a third length greater than the second length of second beam 522 is then connected at its lower surface proximate the other end of third beam 524 to the upper surface of second beam 522 by, for example, tab bonding to form multi-layered probe 550. A separate sheet of an array of, for example plated-up (using processes such as, for example, lithographic processes, such as, for example, photolithographic, stereolithographic, or X-ray lithographic processes, etc), third beams 524 with connected tips 506 (a beam panel) may also be formed corresponding to the spacing and pattern of the array of second beams 522 and then aligned and tab bonded to the corresponding second beams 522 en masse.

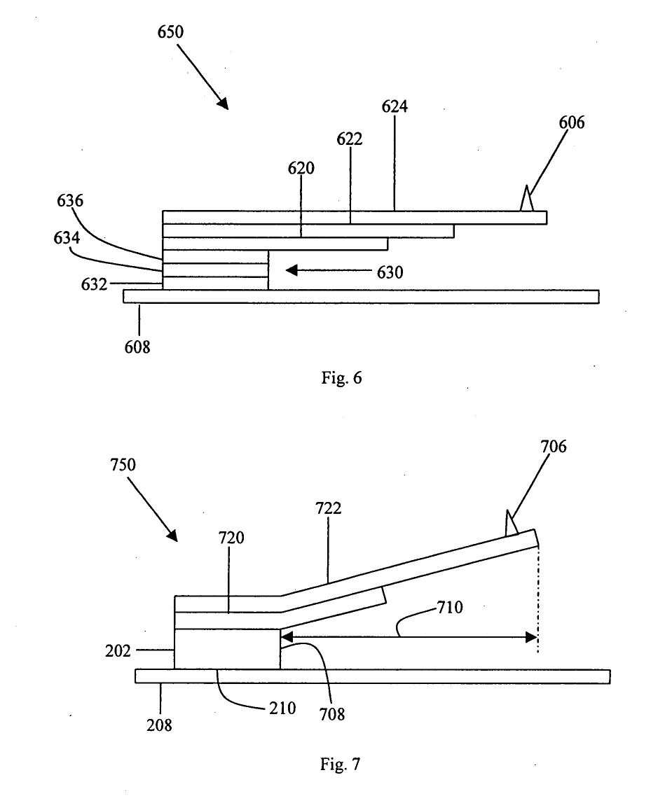

FIG. 6 is a multi-layered probe according to an embodiment of the invention illustrating multi-layered probe 650. Multi-layered probe 650 is analogous to multi-layered probe 550 illustrated in FIG. 5 but, for example, with post 630 itself comprising multiple post segments/layers 632, 634, 636. As in multi-layered probe 550, a three tiered structure of beams 620, 622, 624, each having ever increasing lengths (and tip 606 on the upper surface proximate the distal end of uppermost beam 636) are formed/connected in turn over post segment 636. Each post layer 632, 634, 636 may be formed over substrate 608/each respective lower layer 632, 634 by, for example, forming separate respective, for example, post layer sheets and aligning and connecting them in turn by, for example, tab bonding to the respective substrate 608/lower layer 632, 634. It is noted that post layers 632, 634, 636 may (or may not be) be formed by a plating-up process(es). It is noted that while three post layers 632, 634, 636 are illustrated, any number of post layers may be used by other embodiments. Providing posts in multiple layers may reduced the potential for electrical short circuiting (e.g., bridging) of adjacent posts in close pitch applications.

If post layers 632, 634, 636 and beams 620, 622, 624 (with tip 606 formed on third beam 624) are formed on separate respective post panels and beam panels, then multi-layered probe 650 may be formed by, for example, sequential alignment and bonding processes (e.g., tab bonding) of each panel that may result in increased efficiency.

In an embodiment, post 630 of multi-layered probe 650 may consist of a single post layer (not shown in FIG. 6). A single post layer may be composed of a variety of materials, such as Ni, Cu, Ni—Mn, Ni—Co, and/or a substrate layer with an electrically conductive via. A post layer may be formed using a variety of methods, includes electroplate or laser-form techniques. In an embodiment, the single post layer may be formed using a beam, such as beam 620. In such an embodiment, the post 630 may be formed using one or more beams using the techniques discussed herein. The single post layer may be attached to the substrate 608 using a variety of means, including solder flow, tab bonding, and laser welding. Advantageously, the same techniques for creating a multi-layered probe may also be used to create a post for the multi-layered probe; in effect, a layer of the multi-layer probe acts as the post. Creating a post in this fashion in advantageous, as it allows a pad to be repaired. Thus, if the pad is damaged, the pad may be repaired by creating a new post, using an embodiment of the invention, over the damaged pad.

FIG. 7 is a multi-layered probe according to another embodiment of the invention illustrating multi-layered probe 750. Multi-layered probe 750 is analogous to multi-layered probe 450 illustrated in FIG. 4 but, for example, with each beam 720, 722 (with optional tip 706 connected on the upper surface proximate one end of second beam 722) being bent upwardly proximate, for example, distal edge 708 of post 202. Beams 720, 722 may be formed and connected to post 202/first beam 720 in an analogous manner as described above for the multi-layered probe 450 and then bent together upwardly starting at the edge of post 202. Each beam 720, 722 may be separately formed and bent in the desired configuration with first bent beam 720 connected to post 202 by, for example, tab bonding, and then second bent beam 722 then connected to first bent beam 720 by, for example, tab bonding. Further, beams such as beams 720, 722 could be formed (e.g., through a plating process) to have the desired bend. Again, either individual bent beams 720, 722 may be connected to post 202/first bent beam 720 one at a time, or respective first and second beam sheets may be formed and aligned and connected by, for example, tab bonding, en masse.

Embodiments of the invention take advantage of the observation that by including bends in respective beams 720, 722, the contact force that may be exerted by the distal end of uppermost beam 722/optional tip 706 is increased while also permitting a smaller pitch of the multi-layered probes 750 as distance 710 of the end of second/uppermost beam 722 from distal edge 708 of post 202 may be decreased as compared to a straight beam (see FIG. 4, for example). While only a two layer bent beam probe 750 is shown in FIG. 7, it is contemplated that three or more bent beams of ever increasing length may be formed (analogous to multi-layered probe 550 of FIG. 5, for example, being bent or multi-layered probe 650 of FIG. 6, for example, being bent).

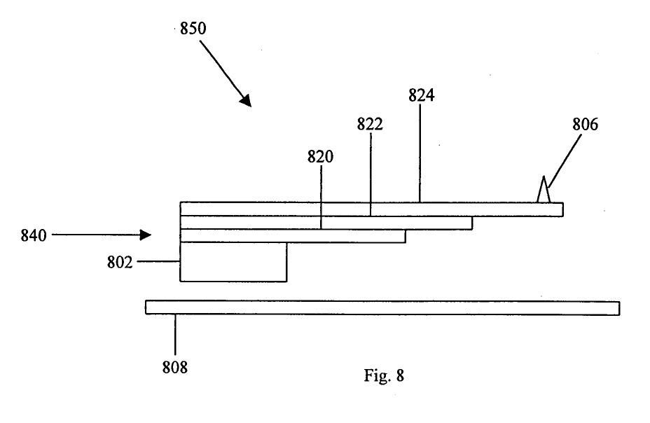

FIG. 8 depicts another embodiment of the invention wherein post and beam structure 850 (such as, for example, a structure analogous to the third exemplary embodiment multi-layered probe 550 illustrated in FIG. 5, for example) is formed separate and apart from substrate 808 and is then connected to substrate 808 by, for example, tab bonding either one by one or from a post and beam structure panel array that is aligned and connected by, for example, tab bonding, to desired or specified locations, traces, or pads on substrate 808.

It is contemplated that any of multi-layered probes 450, 550, 650, 750 may be formed in this manner. In the case of multi-layered probe 750, beams 720, 722 may be bent before or after attachment to substrate 808 as described above.

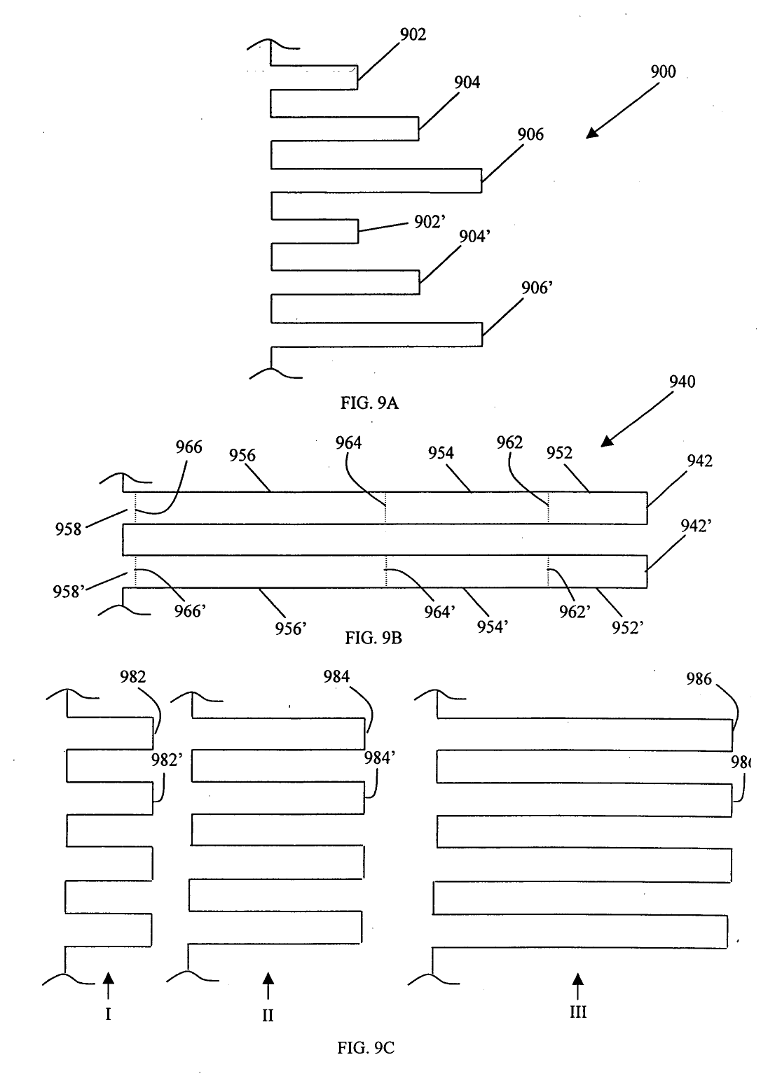

FIG. 9A is yet another exemplary embodiment of the present invention illustrating at least a portion of a series 900 of alternating beams formed on a first structure or substrate with each beam 902, 904, 906 alternating in length from shortest (902) to longest (906). Tips (not shown) may be connected proximate one end of each respective longest (and therefore to be uppermost) beam 906 (906′). When forming a three tiered multi-layered probe (not shown), for example one analogous to multi-layered probe 550 illustrated in FIG. 5, for example, one short beam 902 is removed or harvested from beam series 900 and connected to a post/post structure (generally on a separate, second substrate or structure), then adjacent intermediate length beam 904 is removed from beam series 900 and connected to short beam 902 and then adjacent longest beam 906 is removed from beam series 900 and connected to intermediate beam 904. Beams 902, 904, 906 may be removed from the first structure by cutting or sawing, for example, such as by laser ablation, dicing, etc.

Then for another (second, for example) multi-layered probe (not shown) the adjacent (or other) sequence of beams 902′, 904′, 906′, for example, may be removed in turn to form that multi-layered probe, etc. While sequences of three beams 902, 904, 906; 902′, 904′, 906′ are illustrated in beam series 900, a sequence of two beams or a sequence of four or more beams may comprise beam series 900. It is contemplated that beams 902, 904, 906; 902′, 904′, 906′, . . . , for example, formed on a first structure may be used to form the multi-layered probes (also on the first structure, on a second structure or a second, third, . . . and X number of structures). It is further contemplated that beams 902, 904, 906; 902′, 904′, 906′, . . . , may be in descending order, mixed order or other order. It is also contemplated that for forming a multi-layered probe also having a multi-layered post structure (not shown but analogous to one such as that illustrated in FIG. 6, for example) an additional number Z of post structure layers may be formed within the sequence of beams, for example, in sequence, three post layers, a short beam, an intermediate beam, a long beam, etc.

FIG. 9B is a further embodiment of the invention illustrating at least a portion of a series 940 of equal length beam structures 942, 942′ formed on a first structure or substrate. Beam structure 942, for example, is adapted to be harvested (e.g., such as by cutting, sawing, laser ablation, dicing, etc. prior to the process of bonding the beam structure as part of a probe, or other such cutting processes that may occur in conjunction with the bonding of the beam structure) along dashed lines 962, 964, 966 (which define respective inchoate beams 952, 954, 956) for example, to form beams 952, 954, 956 such that the series of three beams may have increasing lengths approaching root 958. Tips (not shown) may be connected to one end of inchoate longest (and therefore to be uppermost) beam 956. When forming a three tiered multi-layered probe (not shown, but, for example, one analogous to multi-layered probe 550 illustrated in FIG. 5) one short beam 952 is harvested from beam series 940 (e.g., cutting along dashed line 962) and connected to a post/post structure (generally on a separate, second substrate/structure). Adjacent intermediate length beam 954 is then harvested from beam series 940 (such as by, for example, cutting along dashed line 964) and connected to short beam 952. Adjacent longest beam 956 is then harvested from series 900 (such as by, for example, cutting along dashed line 966) and connected to intermediate beam 954. Then for another multi-layered probe (not shown) the adjacent (or other) sequence of beams 952′, 954′, 956′, for example, (defined by dashed lines 962′, 964′, 964′, for example) may be harvested in turn to form that multi-layered probe, etc. It is also contemplated that all first beams 952, 952′, . . . are harvested and connected to respective post/post structures (not shown) before second beams 954, 954′, . . . which are harvested before third beams 956, 956′, . . . , etc.

While a sequences of three inchoate beams 952, 954, 956; 952′, 954′, 956′ are illustrated in each respective beam structure 942; 942′ of beam series 940, a sequence of two inchoate beams or a sequence of four or more inchoate beams may comprise each beam structure in beam series 940. It is further contemplated that beam structures 942, 942′, . . . , for example, formed on a first structure may be used to form multi-layered probes 950, 950′,. . . also on the first structure, on a second structure or a second, third, . . . and X number of structures. It is yet further contemplated that for forming a multi-layered probe also having a multi-layered post structure (not shown but analogous to one such as that illustrated in FIG. 6, for example) each beam series may be lengthened to include two or more inchoate post layers/segments formed distally of inchoate shortest beam 952, 952′, etc., from roots 958, 958′, etc. so that the multi-layered post structure is formed first by harvesting and connecting the two or more post layers/segments, and then the shortest beam 952 is connected to the multi-layered post structure, the intermediate beam 954 is connected to the shortest beam 952 and the longest beam 956 is connected to the intermediate beam 954 to form the multi-layered beam structure (not shown).

FIG. 9C is yet a further exemplary embodiment of the present invention illustrating at least a portion of beam series I, II and III with each having equal length beams 982, 984, 986 therein formed on a single or multiple structure(s) or substrate(s). Tips (not shown) may be connected to one end of longest (and therefore to be uppermost) beam 986. When forming a three tiered multi-layered probe, for example one analogous to multi-layered probe 550 illustrated in FIG. 5, for example, one short beam 982 is removed from beam series I and connected to a post/post structure (generally on a separate, post substrate/structure), then intermediate length beam 984 is removed from beam series II and connected to short beam 982 and then longest beam 986 is removed from beam series III and connected to intermediate beam 984. Then for another multi-layered probe the adjacent (or other) sequence of beams 982′, 984′, 986′, for example, may be removed from respective beam series I, II, III, in turn, to form that probe, etc. While three beam series I, II, III having short, intermediate and long length beams 982, 984, 986 are illustrated in FIG. 9C, two sequences I, II of short and long length beams or four sequences I, II, III, IV of shortest, short, long and longest beams may be employed depending upon the structure of the final multi-layered probe to be formed.

As noted above, each series I, II, III of respective beams 982, 984, 986 may be all formed on a single substrate/structure, or on separate substrates/structures or a combination thereof.

It is also contemplated that for forming a multi-layered probe also having a multi-layered post structure (not shown but analogous to one such as that illustrated in FIG. 6, for example) an additional sequence M of post structure layers may be formed on a (separate) substrate/structure. It is further contemplated that first structure of beams 902, 904, 906; 902′, 904′, 906′, . . . , for example, may be used to form multi-layered probes 950, 950′, . . . also on the first substrate, on a second substrate or a second, third, etc. number of substrates.

Thus, the present invention provides certain advantages in comparison to prior probes. For example, an increased force (along with a reduced beam length) is provided in certain embodiments of the present invention. Further, an increased probe life may be provided, for example, because of the reduced stress on the beams (e.g., the upper beams) of the multi-layered beam structure.

While the present invention has been described primarily with respect to probe cards for wafer testing of semiconductor devices, it is not limited thereto. Certain of the teachings may be applied to other technologies, for example, package testing of semiconductor devices.

In the foregoing specification, embodiments of the invention have been described with reference to numerous specific details that may vary from implementation to implementation. Thus, the sole and exclusive indicator of what is the invention, and is intended by the applicants to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

What is claimed is:

1. A probe for a probe card assembly, comprising:
a post structure supported by a substrate;
a plurality of stacked beam elements disposed on the post structure; and
a tip attached to a surface of a top beam element, of the plurality of stacked beam elements, that opposes the substrate, and wherein the tip is configured to be electrically connected to a semiconductor device to be tested.

2. The probe of claim 1, wherein each of the plurality of beam elements is a different length, and wherein the plurality of beam elements is stacked in order of increasing length.

3. The probe of claim 2, wherein a shortest beam element of the plurality of beam elements is disposed on the post structure.

4. The probe of claim 1, wherein the post structure is composed of one or more post elements.

5. The probe of claim 1, wherein the post structure is made out of the same material as the plurality of beam elements.

6. The probe of claim 1, wherein at least one of the plurality of beam elements are bent in a direction opposing the substrate to cause the tip to be further away from the substrate than the height the post relative to the surface of the substrate.

7. A probe for a probe card assembly, comprising:
two or more stacked beam elements, wherein the lower beam element, in the two or more stacked beam elements, acts a post structure that is supported by a substrate, wherein said lower beam element is disposed on said substrate, and wherein the lower beam element is the shortest of the two or more stacked beam elements; and
a tip attached to a surface of the upper beam element that opposes the substrate, and wherein the tip is configured to be electrically connected to a semiconductor device to be tested.

8. A method for assembling a probe for a probe card assembly, comprising:
forming a post structure disposed on a substrate;
forming a first beam element on the post structure, wherein the first beam element has a first length;
forming a second beam element on the first beam element, wherein the second beam element has a second length, wherein the second length is greater than the first length; and
forming a tip on a surface of the second beam element that opposes the substrate and the end of the second beam element distal to the post, and wherein the tip is configured to be electrically connected to a semiconductor device to be tested.
